(19) United States
(12) Patent Application Publication
(10) Pub. No.: US 2014/0059269 A1
(43) Pub. Date: Feb. 27, 2014

(54) COMPUTING DEVICE AND OPERATING METHOD OF COMPUTING DEVICE

(71) Applicants: Young-jin PARK, Incheon (KR); Ilguy JUNG, Hwaseong-si (KR)

(72) Inventors: Young-jin PARK, Incheon (KR); Ilguy JUNG, Hwaseong-si (KR)

(21) Appl. No.: 14/011,334

(22) Filed: Aug. 27, 2013

(30) Foreign Application Priority Data
Aug. 27, 2012 (KR) 10-2012-0093851

(51) Int. Cl. G06F 12/02; G11C 7/10

(52) U.S. Cl. CPC G06F 12/0238; G11C 7/1072
USPC 711/102; 711/104

(57) ABSTRACT

Exemplary embodiments may provide a computing device which includes a first random access memory; a second random access memory; a memory controller which is configured to control the first random access memory and second random access memory; and a processor which is configured to use the first random access memory and second random access memory, as a working memory, through the memory controller, wherein the memory controller is configured to access one memory, selected by a transferred command from the processor, from among the first random access memory and second random access memory.

### CROSS-REFERENCE TO RELATED APPLICATIONS

This application claims priority from Korean Patent Application No. 10-2012-0093851 filed Aug. 27, 2012 in the Korean Intellectual Property Office, the entire disclosure of which is hereby incorporated by reference.

### BACKGROUND

Exemplary embodiments relate to an electronic device. More particularly, exemplary embodiments relate to a computing device and an operating method thereof.

A semiconductor memory device may be a memory device, which is fabricated using semiconductors such as silicon (Si), germanium (Ge), gallium arsenide (GaAs), indium phosphide (InP), etc. Semiconductor memory devices may be classified into volatile memory devices and nonvolatile memory devices.

The volatile memory device may be a memory device which loses stored data stored at power-off. The volatile memory devices may include a static RAM (SRAM), a dynamic RAM (DRAM), a synchronous DRAM (SDRAM), etc. The nonvolatile memory devices may retain stored contents at power-off. The nonvolatile memory devices include a read only memory (ROM), a programmable ROM (PROM), an electrically programmable ROM (EPROM), an electrically erasable and programmable ROM (EEPROM), a flash memory device, a phase-change RAM (PRAM), a magnetic RAM (MRAM), a resistive RAM (RRAM), a ferroelectric RAM (FRAM), etc.

A related art computing device may use a volatile memory (e.g., DRAM, SRAM, etc.) as a working memory, and a nonvolatile memory (e.g., HDD, flash memory, etc.) as storage. The volatile memory of the related art may lose stored data at power-off. Thus, when a power is again supplied, the computing device may store data at the volatile memory. Research and development has been made to use nonvolatile random access memories (e.g., PRAM, MRAM, FeRAM, RRAM, etc.) as a working memory of a computing device. The goal of the research and development is to improve the performance of the related art computed device.

### SUMMARY

An aspect of an exemplary embodiment may provide a computing device which comprises a first random access memory; a second random access memory; a memory controller configured to control the first random access memory and second random access memory; and a processor configured to use the first random access memory and the second random access memory as a working memory, through the memory controller, wherein the memory controller is configured to access one memory, selected by a transferred command from the processor, from among the first random access memory and second random access memory.

In example embodiments, the first random access memory is a nonvolatile random access memory, and the second random access memory is a volatile random access memory.

In example embodiments, the memory controller accesses the second random access memory when a normal access command is transferred from the processor, and the memory controller accesses the first random access memory when a nonvolatile access command is transferred from the processor.

In example embodiments, the memory controller is configured to manage a nonvolatile data table which includes information on data stored at the first random access memory.

In example embodiments, the nonvolatile data table includes information on an address where data is stored, a process associated with the data, and an identifier of the data.

In example embodiments, the memory controller is configured to store the nonvolatile data table at the first random access memory.

In example embodiments, when the computing device is powered, the memory controller is configured to read the nonvolatile data table from the first random access memory.

In example embodiments, the first random access memory is a first portion of a nonvolatile random access memory and the second random access memory is a second portion of a volatile random access memory.

In example embodiments, when the computing device is powered, the memory controller is configured to reset the second random access memory.

In example embodiments, the memory controller is configured to reset the second random access memory when a normal reset command is received from the processor.

In example embodiments, the memory controller is configured to reset the first random access memory when a nonvolatile reset command is received from the processor.

Another aspect of an exemplary embodiment may provide an operating method of a computing device which uses a first random access memory and a second random access memory as a working memory. The operating method comprises generating data; determining whether the generated data is a first type data or a second type data; and storing the generated data at the first random access memory when the generated data is the first type data, and storing the generated data at the second random access memory when the generated data is the second type data.

In example embodiments, the first type data is data managed to be nonvolatile, the second type data is data managed to be volatile, the first random access memory is a nonvolatile random access memory, and the second random access memory is a volatile random access memory.

In example embodiments, the operating method further comprises generating a first type additional data; determining whether a free storage capacity of the first random access memory is larger than a capacity of the first type additional data; storing the first type additional data at the first random access memory when the free storage capacity is larger than the capacity of the first type additional data; and moving cold data of data stored at the first random access memory to a storage when the free storage capacity is smaller than the capacity of the first type additional data, and storing the first type additional data at the first random access memory.

In example embodiments, the operating method further comprises generating an access request of the first type data; determining whether the first type data corresponding to the access request is stored at the storage; accessing the first type data when the first type data is stored at the first random access memory and not stored at the storage; and moving the first type data to the first random access memory when the first type data is stored at the storage, such that the first type data is accessed at the first random access memory.

In example embodiments, the operating method further comprises deleting data stored at the first random access memory; and moving cold data, which is stored at the storage, to the first random access memory when the free storage capacity of the first random access memory is larger than a reference value according to the deleting.

In example embodiments, the first type data is data managed to be nonvolatile, the second type data is data managed to be volatile, the first random access memory is a first area of a nonvolatile random access memory, and the second random access memory is a second area of a volatile random access memory.

In example embodiments, when the computing device is powered, the first random access memory is not reset and the second random access memory is reset.

In example embodiments, the operating method further comprises generating a first type additional data; determining whether a free storage capacity of the first random access memory is larger than a capacity of the first type additional data; and storing the first type additional data at the first random access memory by decreasing a capacity of the second random access memory by a reference capacity and increasing a capacity of the first random access memory by the reference capacity when the free storage capacity is less than the capacity of the first type additional data.

In example embodiments, the operating method further comprises deleting data stored at the first random access memory; and decreasing a storage capacity of the first random access memory by a reference value and increasing a storage capacity of the second random access memory by the reference value, when the free storage capacity of the first random access memory is larger than the reference value according to the deleting.

Another aspect of an exemplary embodiment may provide an operating method of a memory controller is a computing device. The operating method comprises receiving an access request of a first random access memory from a processor; accessing the first random access memory according to the received access request of the first random access memory; updating a first random access memory table stored in the first random access memory; receiving an access request of a second random access memory from the processor; and accessing the second random access memory according to the received access request of the second random access memory.

### BRIEF DESCRIPTION OF THE DRAWINGS

The above and other aspects and features of the exemplary embodiments will become apparent from the following description of the exemplary embodiments with reference to the following figures, wherein like reference numerals refer to like parts throughout the various figures unless otherwise specified, and wherein

FIG. 1 is a block diagram schematically illustrating a computing device according to an embodiment.

FIG. 2 is a flow chart illustrating an operating method of a computing device of FIG. 1 according to an embodiment.

FIG. 3 is a diagram illustrating a nonvolatile data table according to an embodiment.

FIG. 4 is a diagram illustrating functions used at coding of an application program (or, process).

FIG. 5 is a flow chart illustrating an operating method of a computing device of FIG. 1 according to another embodiment.

FIG. 6 is a block diagram schematically illustrating a computing device according to another embodiment.

FIG. 7 is a flow chart illustrating an operating method of a computing device of FIG. 6 according to an embodiment.

FIG. 8 is a flow chart illustrating an operating method of a computing device of FIG. 6 according to another embodiment.

FIG. 9 is a flow chart illustrating an operating method of a computing device of FIG. 1 or 6 according to still another embodiment.

FIG. 10 is a block diagram illustrating a software layer driven at a computing device according to an embodiment.

FIG. 11 is a flow chart illustrating a method in which an operating system of FIG. 10 manages a nonvolatile area and a volatile area.

FIG. 12 is a flow chart illustrating another method in which an operating system of FIG. 10 manages a nonvolatile area and a volatile area.

FIG. 13 is a flow chart illustrating still another method in which an operating system of FIG. 10 manages a nonvolatile area and a volatile area.

FIG. 14 is a flow chart illustrating still another method in which an operating system of FIG. 10 manages a nonvolatile area and a volatile area.

FIG. 15 is a flow chart illustrating still another method in which an operating system of FIG. 10 manages a nonvolatile area and a volatile area.

### DETAILED DESCRIPTION OF THE EXEMPLARY EMBODIMENTS

Embodiments will be described in detail with reference to the accompanying drawings. The exemplary embodiments, however, may be embodied in various different forms, and should not be construed as being limited only to the illustrated embodiments. Rather, these embodiments are provided as examples so that this disclosure will be thorough and complete, and will fully convey the concept of the exemplary embodiments to those skilled in the art. Accordingly, known processes, elements, and techniques are not described with respect to some of the embodiments. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the exemplary embodiments.

Spatially relative terms, such as “beneath”, “below”, “lower”, “under”, “above”, “upper”, etc., may be used herein for ease of description to describe one element or feature's relationship to another element(s) or feature(s), as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations), and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only, and is not intended to be limiting of the exemplary embodiments. As used herein, the singular forms “a”, “an”, and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which the exemplary embodiments belong. It will be further understood that terms, such as those defined in commonly used dictionaries, should be interpreted as having a meaning that is consistent with their meaning in the context of the relevant art and/or the present specification, and will not be interpreted in an idealized or overly formal sense unless expressly so defined herein.

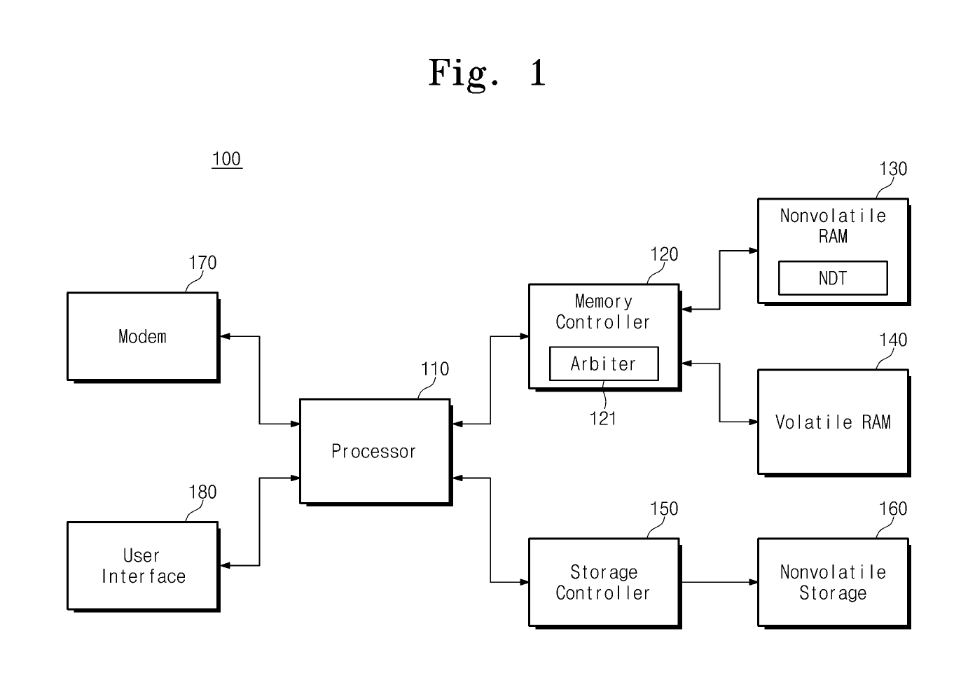

FIG. 1 is a block diagram schematically illustrating a computing device according to an embodiment. Referring to FIG. 1, a computing device 100 may include a processor 110, a memory controller 120, a nonvolatile random access memory 130, a volatile random access memory 140, a storage controller 150, a nonvolatile storage 160, a modem 170, and a user interface 180.

The processor 110 may be configured to control an overall operation of the computing device 100. The processor 110 may perform a logical operation, and may control components of the computing device 100. The processor 110 may include a general-purpose processor, an application processor, etc.

The memory controller 120 may be configured to control the nonvolatile random access memory 130 and the volatile random access memory 140, according to a control of the processor 110. The memory controller 120 may control write, read, and erase operations of the nonvolatile random access memory 130 and the volatile random access memory 140. The nonvolatile random access memory 130 and the volatile random access memory 140 may be used as a working memory of the processor 110.

The nonvolatile random access memory 130 may include a flash memory device, a phase-change RAM (PRAM), a magnetic RAM (MRAM), a resistive RAM (ReRAM), a ferroelectric RAM (FRAM), etc. The volatile random access memory 140 may include a static RAM (SRAM), a dynamic RAM (DRAM), a synchronous DRAM (SDRAM), etc.

The memory controller 120 may include an arbiter 121. The arbiter 121 may determine an address and a capacity of each of the nonvolatile random access memory 130 and the volatile random access memory 140, to transfer information on a determined result to the processor 110.

The arbiter 121 may determine whether to access the nonvolatile random access memory 130 or the volatile random access memory 140, in response to an access command from the processor 110. For example, as a memory to be accessed, the arbiter 121 may select one of the nonvolatile random access memory 130 and the volatile random access memory 140 according to an address from the processor 110. As a memory to be accessed, the arbiter 121 may select one of the nonvolatile random access memory 130 and the volatile random access memory 140 according to a type of command transferred from the processor 110.

The memory controller 120 may be configured to drive a nonvolatile data table NDT. The nonvolatile data table NDT may include information associated with data stored at the nonvolatile random access memory 130.

The memory controller 120 may read and drive the nonvolatile data table NDT stored at the nonvolatile random access memory 130. The nonvolatile data table NDT updated at the memory controller 120 may be stored at the nonvolatile random access memory 130, according to a predetermined condition.

The memory controller 120 may manage the nonvolatile data table NDT in a manner where the nonvolatile data table NDT is directly accessed, instead of reading and driving the nonvolatile data table NDT stored at the nonvolatile random access memory 130.

The storage controller 150 may control the nonvolatile storage 160 according to a control of the processor 110. The storage controller 150 may control write, read, and erase operations of the nonvolatile storage 160. The nonvolatile storage 160 may be used as an auxiliary memory device of the computing device 100. The nonvolatile storage 160 may be used to store long-term data. The nonvolatile storage 160 may include a hard disk drive, a solid state drive, a flash memory, a phase-change RAM (PRAM), a magnetic RAM (MRAM), a resistive RAM (ReRAM), a ferroelectric RAM (FRAM), etc.

The modem 170 may communicate with an external device according to a control of the processor 110. The modem 170 may communicate with an external device according to various communication protocols such as Ethernet, Bluetooth, WiFi, WiMax, CDMA, LTE, ATDMB, NFC, etc.

The user interface 180 may exchange data with the external device according to a control of the processor 110. The user interface 180 may include user input interfaces such as a keyboard, a mouse, a touch pad, a touch panel, a microphone, a camera, a sensor, etc. The user interface 180 may include user output interfaces such as a monitor, a screen, a speaker, a ramp, a motor, etc.

The user interface 180 may include communication ports such as a USB port, an SATA port, an SD port, an SDHC port, etc.

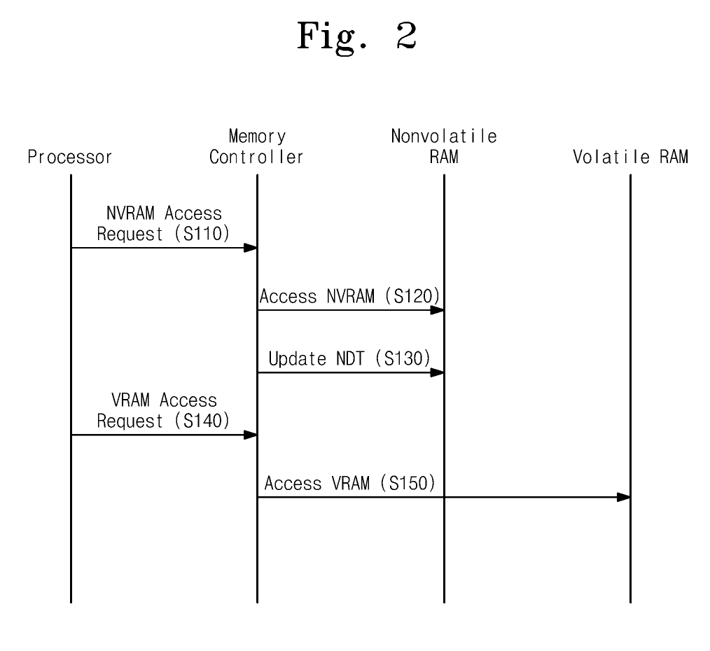

FIG. 2 is a flow chart illustrating an operating method of a computing device of FIG. 1 according to an embodiment. Referring to FIGS. 1 and 2, in operation S110, a processor 110 may transfer an access request of a nonvolatile random access memory 130 to a memory controller 120. The access request may include an address indicating the nonvolatile random access memory 130 or a command indicating the nonvolatile random access memory 130.

In operation S120, the memory controller 120 may access the nonvolatile random access memory 130 according to the access request of the processor 110. An arbiter 121 may determine whether the access request is a request on the nonvolatile random access memory 130. The memory controller 120 may access the nonvolatile random access memory 130 based on a nonvolatile data table NDT.

In operation S130, the memory controller 120 may update the nonvolatile data table NDT stored at the nonvolatile random access memory 130. In the case that the memory controller 120 reads and drives the nonvolatile data table NDT stored at the nonvolatile random access memory 130, it may update the nonvolatile data table NDT whenever the driven nonvolatile data table NDT is updated, whenever the nonvolatile data table NDT is updated by a predetermined number, whenever a time elapses after the nonvolatile data table NDT is updated, or according to a predetermined schedule. In the case that the memory controller 120 directly accesses and manages the nonvolatile data table NDT stored at the nonvolatile random access memory 130, the memory controller 120 may update the nonvolatile data table NDT whenever data of the nonvolatile random access memory 130 is changed.

In operation S140, the processor 110 may transfer an access request of a volatile random access memory 140 to the memory controller 120. The access request may include an address indicating the volatile random access memory 140 or a command indicating the volatile random access memory 140.

In operation S150, the memory controller 120 may access the volatile random access memory 140. Data stored at the volatile random access memory 140 may not be managed using a separate table.

With an embodiment, an operating method of a computing device 100 may include the nonvolatile random access memory 130 and the volatile random access memory 140. Data with the high status may be stored at the nonvolatile random access memory 130. Data with the low status may be stored at the volatile random access memory 140.

In example embodiments, the volatile random access memory 140 may be used to store data which does not require a long-term storage of working data. Examples of data which does not require a long-term storage include a moving picture replay program, a music replay program, etc.

The nonvolatile random access memory 130 may be used to store temporary save data of temporary data of a game program, and the volatile random access memory 140 may be used to store the remaining working data.

Working data associated with a sleep mode, from among working data of a mobile system, may be stored at the nonvolatile random access memory 130, and the remaining working data may be stored at the volatile random access memory 140.

User identification information (e.g., a password) of working data of an internet browsing program may be stored at the nonvolatile random access memory 130, and the remaining working data may be stored at the volatile random access memory 140.

The nonvolatile random access memory 130 may be used to store working data of a program associated with a system management and job, such as working data associated with SQL (Structured Query Language), working data associated with an office program, working data associated with a virtualization program, working data associated with a main server, and working data associated with a virus vaccine program.

If important data is stored at the nonvolatile random access memory 130, data of programs driven at the computing device 100 may be retained when the computing device 100 is terminated due to an error, or when the computing device 100 is powered off.

For example, it is assumed that the computing device is driven again after it is stopped, due to an error or power interruption. In this case, since temporary save data of a game program is stored at the nonvolatile random access memory 130, the game program may be resumed normally. Likewise, if data associated with a power saving mode of a mobile system is stored at the nonvolatile random access memory 130, the mobile system may be recovered without data damage. If important data associated with an internet browsing program is stored at the nonvolatile random access memory 130, a lastly visited internet site may be recovered. A last location and data of SQL and a database may be also recovered. If critical data of a main server is stored at the nonvolatile random access memory 130, it is possible to prevent mail being transmitted from be lost. If critical data associated with a virtualization program is stored at the nonvolatile random access memory 130, a last process executed by the virtualization program may be recovered. If important data associated with an office program is stored at the nonvolatile random access memory 130, it is possible to prevent an office file not stored from being lost. If critical data of a virus vaccine program is stored at the nonvolatile random access memory 130, virus tracking and removal may be normally resumed.

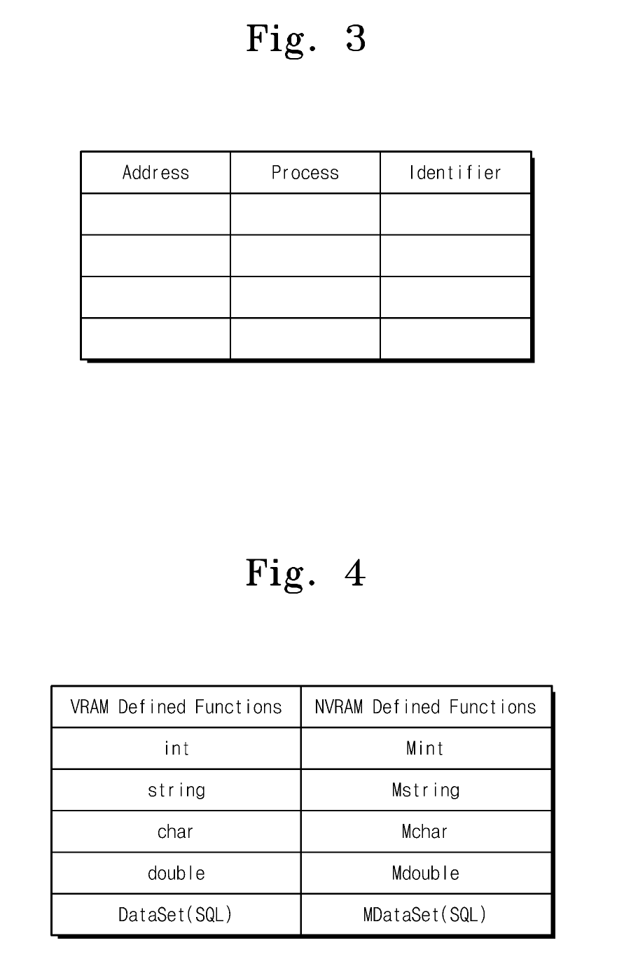

FIG. 3 is a diagram illustrating a nonvolatile data table according to an embodiment. Referring to FIGS. 1 and 3, a nonvolatile data table NDT may indicate an address field, a process field, and an identifier field.

The address field may include information on addresses of a nonvolatile random access memory 130, at which data is stored.

The process field may include information on a process (e.g., an application program) associated with data.

The identifier field may include information on an identifier conferred onto a process, to identify data.

In example embodiments, whether to store working data at the nonvolatile random access memory 130 or a volatile random access memory 140 may be decided by an application program (or, a process). At coding to the application program (or, a process), important working information may be coded to be stored at the nonvolatile random access memory 130, and other information may be coded to be stored at the volatile random access memory 140.

When a specific application program (or, a process) calls a variable having a specific identifier, a memory controller 120 may determine whether a corresponding variable is stored at the nonvolatile random access memory 130, based on the nonvolatile data table NDT. When a specific process defines a variable having a specific identifier, the nonvolatile data table NDT may be updated to include corresponding process, identifier, and address.

Like the application program (or, progress), an operating system or working data may be distributed into the nonvolatile random access memory 130 and the volatile random access memory 140. For example, working data associated with backup, program install, program delete, recovery, and update of an application program may be stored at the nonvolatile random access memory 130.

FIG. 4 is a diagram illustrating functions used at coding of an application program (or, process). Referring to FIG. 4, NVRAM (nonvolatile RAM) defined functions and VRAM (volatile RAM) defined functions may be used.

A function “int” may define an integer type of variable, which is stored at a volatile random access memory 140. A function “Mint” may define an integer type of variable, which is stored at a nonvolatile random access memory 130.

A function “string” may define a character string type of variable, which is stored at the volatile random access memory 140. A function “Mstring” may define a character string type of variable, which is stored at the nonvolatile random access memory 130.

A function “char” may define a character type of variable, which is stored at the volatile random access memory 140. A function “Mchar” may define a character type of variable, which is stored at the nonvolatile random access memory 130.

A function “double” may define a number (including the decimal) type of variable, which is stored at the volatile random access memory 140. A function “Mdouble” may define a number (including the decimal) type of variable, which is stored at the nonvolatile random access memory 130.

A function “DataSet” may define an SQL data set type of variable, which is stored at the volatile random access memory 140. A function “MDataSet” may define an SQL data set type of variable, which is stored at the nonvolatile random access memory 130.

In addition to the functions illustrated in FIG. 4, other functions for defining working data used at the application program (or, process) may be designed to be stored at the nonvolatile random access memory 130 and the volatile random access memory 140.

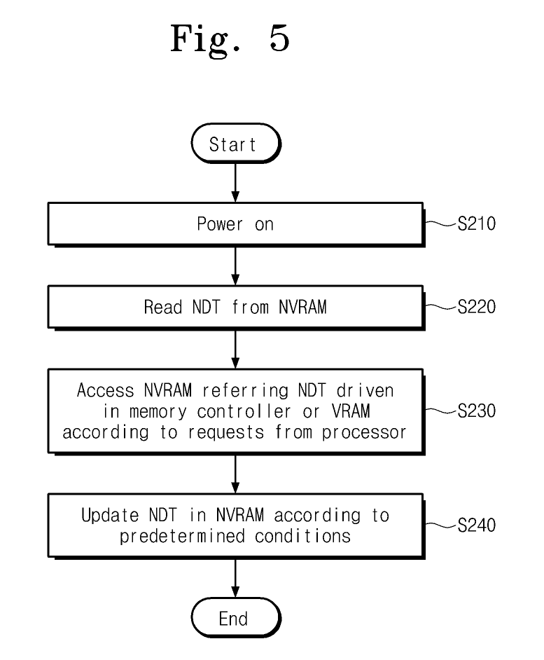

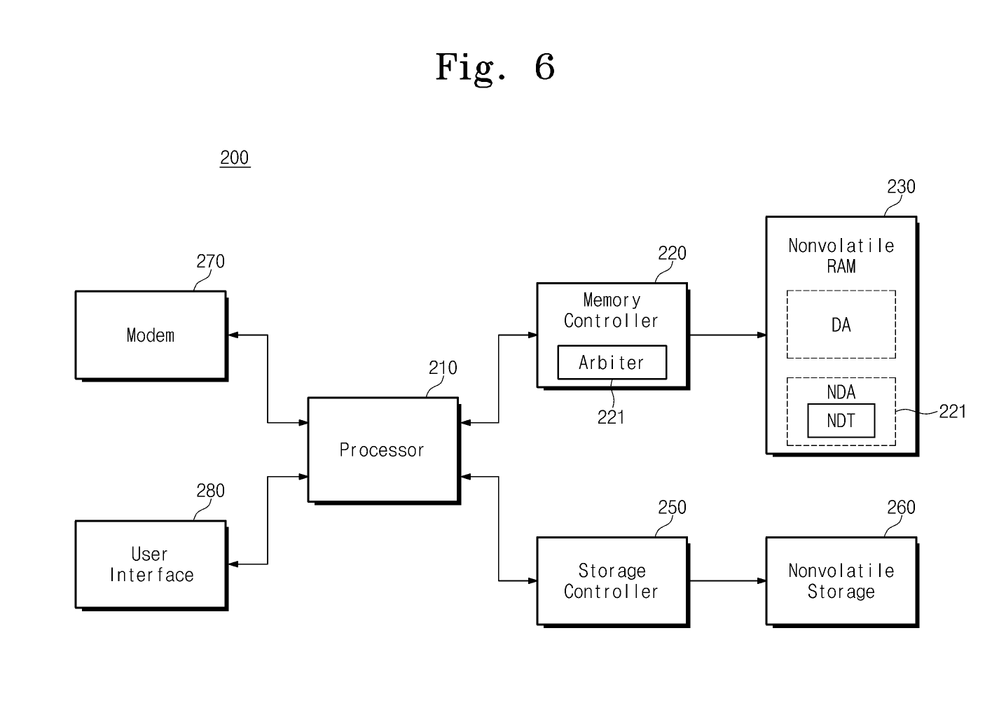

FIG. 5 is a flow chart illustrating an operating method of a computing device of FIG. 1 according to another embodiment. In FIG. 5, there is illustrated an operation of a memory controller 120.

Referring to FIGS. 1 and 5, in operation S210, a computing device 100 may be powered on.

In operation S220, a memory controller 120 may read a nonvolatile data table NDT from a nonvolatile random access memory 130.

In operation S230, upon a request from a processor 110, the memory controller 120 may access the nonvolatile random access memory 130 or a volatile random access memory 140 based on the nonvolatile data table NDT.

In operation S240, the memory controller 120 may update the nonvolatile data table NDT stored at the nonvolatile random access memory 130 according to a predetermined condition. The predetermined condition may include a condition that the nonvolatile data table NDT is driven at the memory controller 120 is updated, that the nonvolatile data table NDT is updated by a predetermined number, that a time elapses after the nonvolatile data table NDT is updated, or a predetermined schedule.

In the condition that the memory controller 120 directly accesses and manages the nonvolatile data table NDT stored at the nonvolatile random access memory 130, the operation S220 may be skipped. The predetermined condition in operation S240 may a condition that the nonvolatile data table NDT is updated.

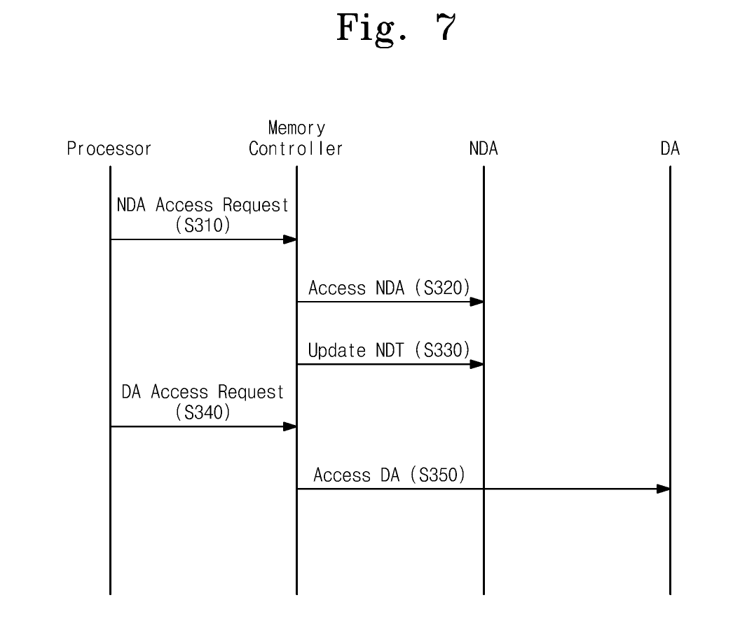

FIG. 6 is a block diagram schematically illustrating a computing device according to another embodiment. Referring to FIG. 6, a computing device 200 may include a processor 210, a memory controller 220, a nonvolatile random access memory 230, a storage controller 250, a nonvolatile storage 260, a modem 270, and a user interface 280.

The processor 210 may be configured to control an overall operation of the computing device 200.

The memory controller 220 may be configured to control the nonvolatile random access memory 230 according to a control of the processor 210. The memory controller 220 may include an arbiter 221.

The arbiter 221 may configure a delete area DA and a non-delete area NDA at the nonvolatile random access memory 230. The delete area DA may be an area which is reset according to a normal reset request sent from the processor 210. The non-delete area NDA may be an area which is not reset, according to the normal reset request sent from the processor 210. The non-delete area NDA may be an area which is reset according to a separate reset request (e.g., a nonvolatile reset request).

The arbiter 221 may determine whether to access any one of the delete area DA and the non-delete area NDA of the nonvolatile random access memory 230 according to an access request transferred from the processor 210. The arbiter 221 may determine whether to access any one of the delete area DA and the non-delete area NDA of the nonvolatile random access memory 230 according to an address or a type of command transferred from the processor 210.

The memory controller 220 may provide the processor 210 with a capacity or address of the nonvolatile random access memory 230, a capacity or address of the delete area DA, or a capacity or address of the non-delete area NDA.

The memory controller 220 may drive a nonvolatile data table NDT. The nonvolatile data table NDT may be stored at the non-delete area NDA.

The memory controller 220 may read and drive the nonvolatile data table NDT stored at the non-delete area NDA. The nonvolatile data table NDT updated at the memory controller 220 may be stored at the non-delete area NDA, according to a predetermined condition.

The memory controller 220 may manage the nonvolatile data table NDT in a manner where the nonvolatile data table NDT is directly accessed, instead of reading and driving the nonvolatile data table NDT stored at the nonvolatile random access memory 230.

The components 250 to 280 of FIG. 6 may be configured similar to components 150 to 180 of FIG. 1.

FIG. 7 is a flow chart illustrating an operating method of a computing device of FIG. 6 according to an embodiment. Referring to FIGS. 6 and 7, in operation S310, a processor 210 may transfer an access request of a non-delete area NDA to a memory controller 220. The access request may include an address or command indicating the non-delete area NDA.

In operation S320, the memory controller 220 may access the non-delete area NDA.

In operation S330, the memory controller 220 may update a nonvolatile data table NDT.

In operation S340, the processor 210 may transfer an access request of a delete area DA to the memory controller 220.

In operation S350, the memory controller 220 may access the delete area DA.

Operations S310 to S350 may be performed similar to operations S110 to S150 of FIG. 2, except that a nonvolatile random access memory 130 is changed into the non-delete area NDA and a volatile random access memory 140 is changed into the delete area DA.

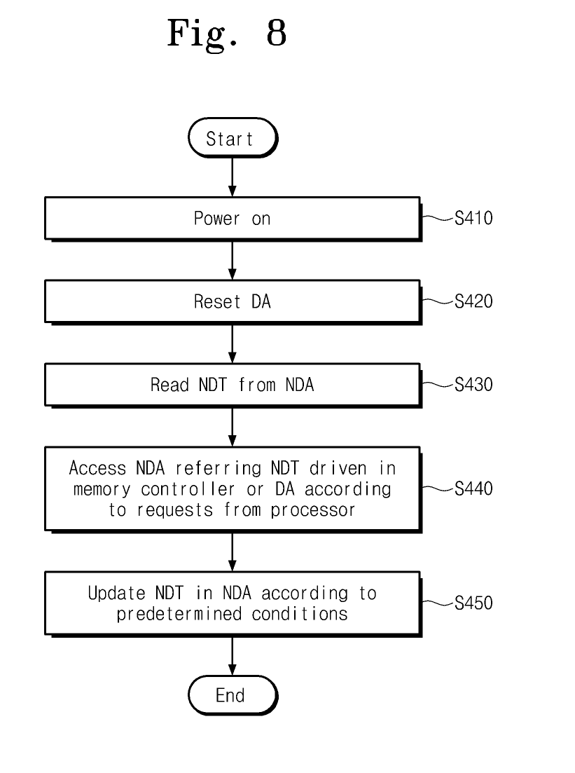

FIG. 8 is a flow chart illustrating an operating method of a computing device of FIG. 6 according to another embodiment. In FIG. 8, an operation of a memory controller 220 may be exemplarily illustrated.

Referring to FIGS. 6 and 8, in operation S410, a computing device 200 may be powered on.

In operation S420, a memory controller 220 may reset a delete area DA. The memory controller 220 may reset the delete area DA according to a reset request of a processor 210.

In operation S430, the memory controller 220 may read a nonvolatile data table NDT from a non-delete area NDA.

In operation S440, upon a request from the processor 210, the memory controller 220 may access the non-delete area NDA or the delete area DA based on the nonvolatile data table NDT.

In operation S450, the memory controller 220 may update the nonvolatile data table NDT stored at the non-delete area NDA according to a predetermined condition. The predetermined condition may include a condition that the nonvolatile data table NDT driven at the memory controller 120 is updated, that the nonvolatile data table NDT is updated by a predetermined number, that a time elapses after the nonvolatile data table NDT is updated, or a predetermined schedule.

In the condition that the memory controller 120 directly accesses and manages the nonvolatile data table NDT stored at the non-delete area NDA, the operation S430 may be skipped. The predetermined condition in operation S450 may be a condition that the nonvolatile data table NDT is updated.

Operations S410 to S450 may be performed similar to operations S210 to S250 of FIG. 5, except that a nonvolatile random access memory 130 is changed into the non-delete area NDA and a volatile random access memory 140 is changed into the delete area DA.

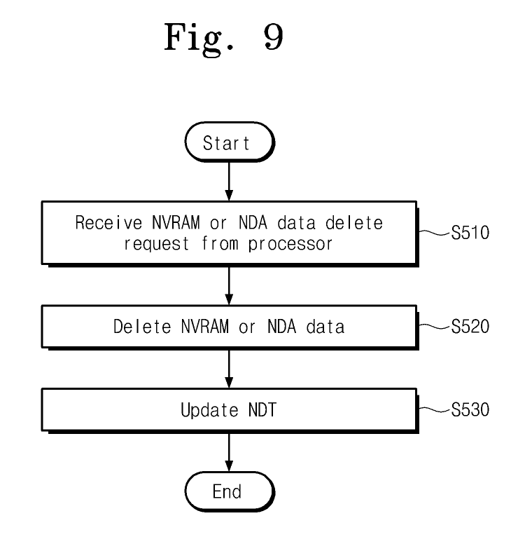

FIG. 9 is a flow chart illustrating an operating method of a computing device of FIG. 1 or 6 according to still another embodiment. Referring to FIGS. 1, 6, and 9, in operation S510, a memory controller 120 or 220 may receive a delete request on a nonvolatile random access memory 130 or a non-delete area NDA from a processor 110 or 210.

In operation S520, the memory controller 120 or 220 may delete data of the nonvolatile random access memory 130 or the non-delete area NDA according to the delete request.

In operation S530, the memory controller 120 or 220 may update a nonvolatile data table NDT according to the deleted data.

In example embodiments, when an application program (or, process) is deleted, a processor 110 or 210 may request the memory controller 120 or 220 to delete data associated with the deleted application program (or, process). A data delete request may be performed by the application program (or, process). Data may be deleted by an operating system of a computing device 100 or 200. Deleting of data may be performed by a separate delete request, which is distinguished from a delete request of a volatile random access memory 140 or a delete area DA. Deleting of data may include resetting of the nonvolatile random access memory 130 or the non-delete area NDA.

In example embodiments, the nonvolatile random access memory 130 or the non-delete area NDA may support an overwrite operation. In this case, operation S520 may be skipped. In other words, the computing device 100 or 200 may invalidate data by updating the nonvolatile data table NDT. When new data is stored at the nonvolatile random access memory 130 or the non-delete area NDA, it may be overwritten on invalidated data.

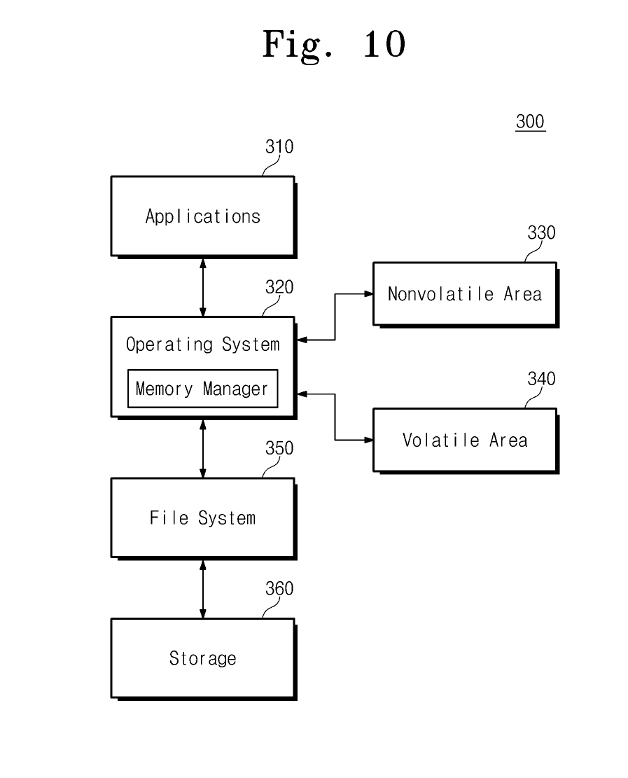

FIG. 10 is a block diagram illustrating a software layer driven at a computing device according to an embodiment. Referring to FIGS. 1, 6, and 10, an application program 310 may operate under a support of an operating system 320. The application program 310 may include a variety of software such as a moving picture replay program, a music replay program, a game, an internet browser, SQL, database, an office program, a virtualization program, a virus vaccine program, etc.

The operating system 320 may control a computing system 100 or 200. The operating system 320 may allocate and manage resources of the computing system 100 or 200 such that the application program 310 is driven.

The operating system 320 may include a memory manager 321. The memory manager 321 may manage a working memory of the computing system 100 or 200. The memory manager 321 may include a nonvolatile area 330 and a volatile area 340. The nonvolatile area 330 may include a nonvolatile random access memory 130 or a non-delete area NDA. The volatile area 340 may include a volatile random access memory 140 or a delete area DA.

A file system 340 may control storage 360 according to a control of the operating system 320.

The memory manager 321 may access the nonvolatile area 330 or the volatile area 340 according to a request of the application program 310 or the operating system 320. In example embodiments, the memory manager 321 may receive information on the nonvolatile area 330 and the volatile area 340 from a memory controller 120 or 220. Based on the received information, the memory controller 321 may generate an address or command to access the nonvolatile area 330, and an address or command to access the volatile area 340.

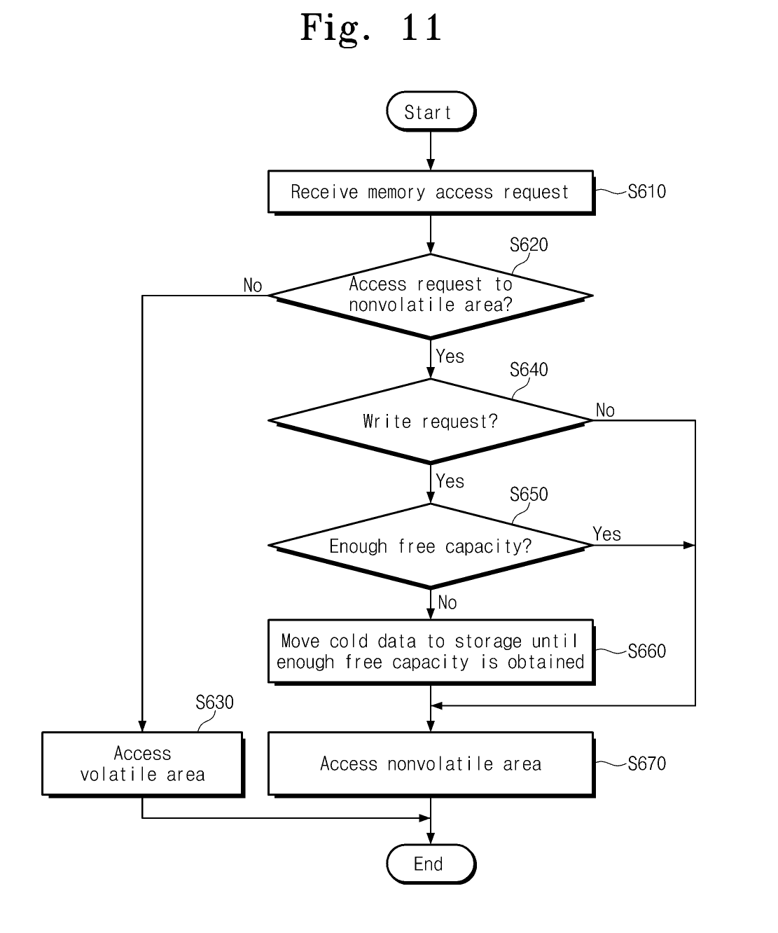

FIG. 11 is a flow chart illustrating a method in which an operating system of FIG. 10 manages a nonvolatile area and a volatile area. Referring to FIGS. 10 and 11, in operation S610, an operating system 320 may receive a memory access request. The operating system 320 may receive the memory access request from an application program 310. The operating system 320 may generate the memory access request according to a predetermined schedule. The memory access request may include information indicating whether it is an access request on a nonvolatile area 330 or an access request on a volatile area 340.

In operation S620, whether the memory access request is a request on the nonvolatile area 330 may be determined. If the memory access request is a request on the volatile area 340, the volatile area 340 may be accessed (operation S630). If the memory access request is a request on the nonvolatile area 330, the method proceeds to operation S640.

In operation S640, whether the access request is a write request may be determined. If the access request is not the write request, the nonvolatile area 330 may be accessed (operation S670). If the access request is the write request, the method proceeds to operation S650.

In operation S650, whether a free capacity of the nonvolatile area 330 is enough may be determined. For example, whether a free capacity of the nonvolatile area 330 is larger than a capacity of write requested data may be determined. If the free capacity is enough, the nonvolatile area 330 may be accessed (operation S670). If the free capacity is not enough, the method proceeds to operation S660.

In operation S660, cold data may be moved to storage 360 until a sufficient free capacity is obtained. The cold data may be data of the nonvolatile area 330 having an access frequency lower than a reference value. Data having the lowest access frequency may be first moved to the storage 360. If the free capacity of the nonvolatile area 330 is sufficiently obtained, the nonvolatile area 330 may be accessed (operation S670).

The operating system 320 may manage information on data, moved to the storage 360, from among data defined to be stored at the nonvolatile area 330.

With the exemplary embodiments, in the case that a free capacity of the nonvolatile area 330 write requested is not enough, cold data of the nonvolatile area 330 may be moved to the storage 360. Thus, a write request may be processed without errors by securing a free capacity of the nonvolatile area 330.

The method of FIG. 11 may be applied to the case that the nonvolatile area 330 is a nonvolatile random access memory 130 or a non-delete area NDA, and the case that a volatile area 340 is a volatile random access memory 140 or a delete area DA.

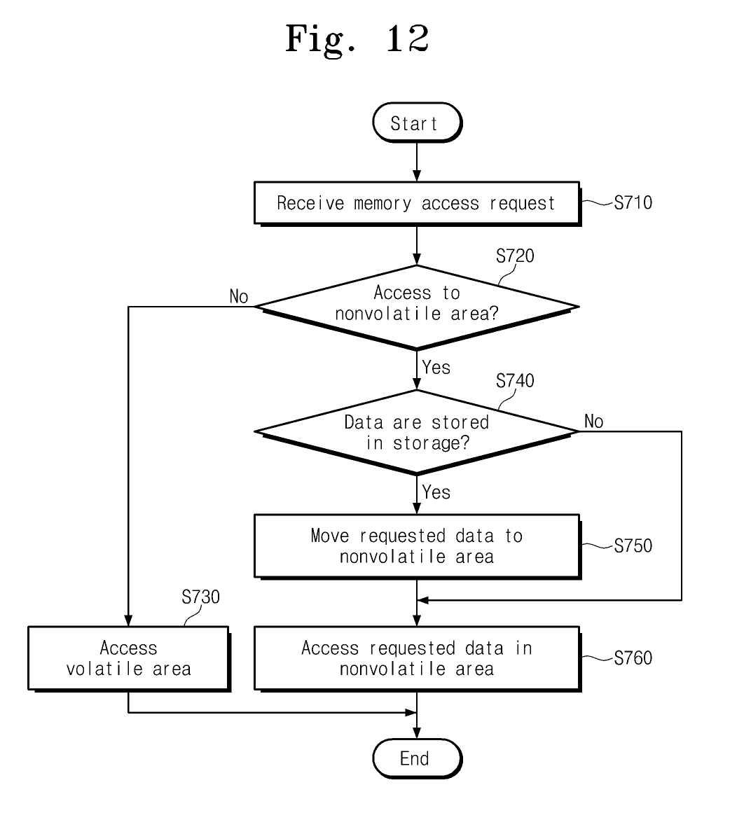

FIG. 12 is a flow chart illustrating another method in which an operating system of FIG. 10 manages a nonvolatile area and a volatile area. Referring to FIGS. 10 and 12, an operating system 320 may receive a memory access request (operation S710). The operating system 320 may receive the memory access request from an application program 310. The operating system 320 may generate the memory access request according to a predetermined schedule. The memory access request may include information indicating whether it is an access request on a nonvolatile area 330, or an access request on a volatile area 340.

In operation S720, whether the memory access request is a request on the nonvolatile area 330 may be determined. If the memory access request is a request on the volatile area 340, the volatile area 340 may be accessed (operation S730). If the memory access request is a request on the nonvolatile area 330, the method proceeds to operation S740.

In operation S740, whether request data is stored at storage 360 may be determined. If data is not stored at storage 360, the nonvolatile area 330 may be accessed (operation S760). If data is stored at storage 360, the method proceeds to operation S750.

In operation S750, the requested data may be moved to the nonvolatile area 330 from the storage 360. Then, in operation S760, the requested data may be accessed at the nonvolatile area 330.

In example embodiments, an operation of moving data stored at the storage 360 to the nonvolatile area 330 may be executed when a predetermined condition is satisfied. For example, in the case that the number of data access operations executed during a reference time is more than a reference value, corresponding data may be moved to the nonvolatile area 330. If the predetermined condition is not satisfied, data may not be moved. Therefore, an access request on the nonvolatile area 330 may be performed by accessing the storage 360.

The method of FIG. 12 may be applied to the case that the nonvolatile area 330 is a nonvolatile random access memory 130 or a non-delete area NDA, and the case that a volatile area 340 is a volatile random access memory 140 or a delete area DA.

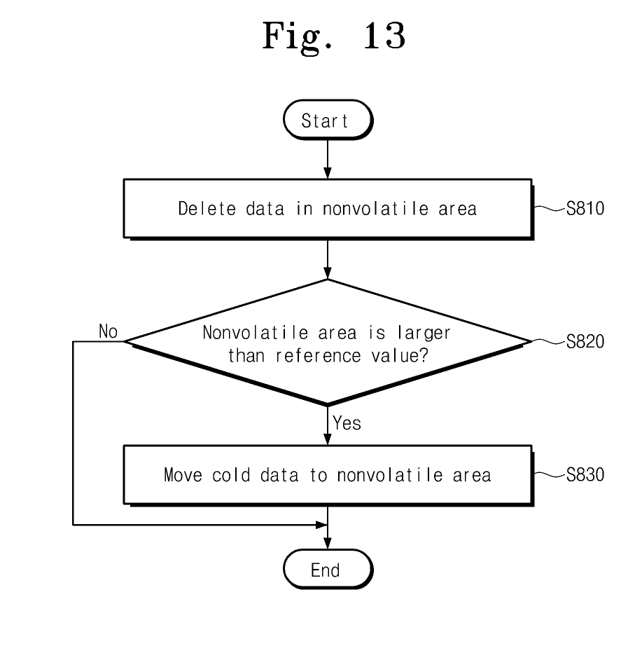

FIG. 13 is a flow chart illustrating still another method in which an operating system of FIG. 10 manages a nonvolatile area and a volatile area. Referring to FIGS. 10 and 13, in operation S810, an operating system 320 may delete data of a nonvolatile area 330. The operating system 320 may receive a delete request from an application program 310 to delete data according to a delete request. The operating system 320 may sense delete of the application program 310 to delete data associated with the deleted application program. The operating system 320 may delete data according to a predetermined schedule. The delete may include delete of data stored at a nonvolatile area 330 or invalidation of data through updating of a nonvolatile data table NDT.

In operation S820, whether cold data stored at the storage 360 exists and a free capacity of the nonvolatile area 330 is larger than a reference value may be determined. For example, the reference value may be a capacity of cold data. The reference value may be a capacity of times of the cold data. The reference value may be a capacity corresponding to a specific ratio of the whole capacity. If the condition is satisfied, the method proceeds to operation S830.

In operation S830, cold data stored at the storage 360 may be moved to the nonvolatile area 330.

The method of FIG. 13 may be applied to the case that the nonvolatile area 330 is a nonvolatile random access memory 130 or a non-delete area NDA, and the case that a volatile area 340 is a volatile random access memory 140 or a delete area DA.

In FIGS. 1 to 13, there is described an example where data of the nonvolatile area 330 is moved to the storage 360. However, data of the nonvolatile area 330 may not be moved to the storage 360.

In example embodiments, a nonvolatile data table NDT may further comprise an importance field. In a case where a free capacity of the nonvolatile area 330 is not enough, data having low importance may be deleted according to the importance level. The deleting of data may include deleting of data stored at the nonvolatile area 330 or invalidation of data through updating of the nonvolatile data table NDT. Management of nonvolatile data according to the importance may be performed by a memory controller 120 or 220 (refer to FIG. 1 or 6), or an operating system 320.

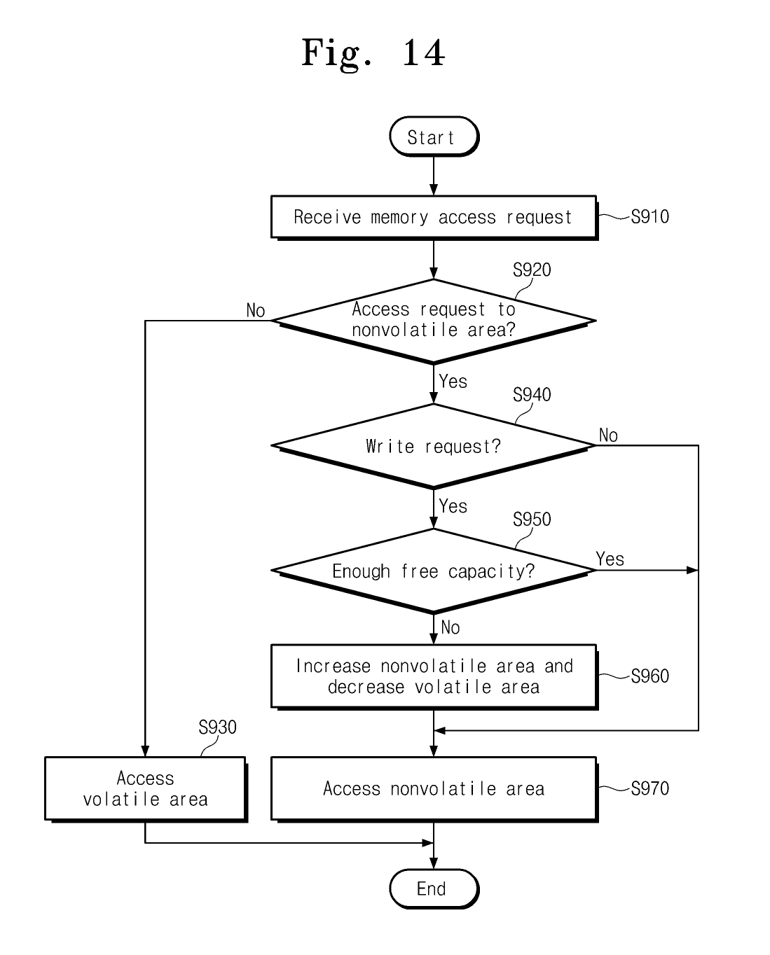

FIG. 14 is a flow chart illustrating still another method in which an operating system of FIG. 10 manages a nonvolatile area and a volatile area. Referring to FIGS. 10 and 14, in operation S910, an operating system 320 may receive a memory access request. The operating system 320 may receive the memory access request from an application program 310. The operating system 320 may generate the memory access request according to a predetermined schedule. The memory access request may include information indicating whether it is an access request on a nonvolatile area 330, or an access request on a volatile area 340.

In operation S920, whether the memory access request is a request on the nonvolatile area 330 may be determined. If the memory access request is a request on the volatile area 340, the volatile area 340 may be accessed (operation S930). If the memory access request is a request on the nonvolatile area 330, the method proceeds to operation S940.

In operation S940, whether the access request is a write request may be determined. If the access request is not a write request, the nonvolatile area 330 may be accessed (operation S970). If the access request is a write request, the method proceeds to operation S950.

In operation S950, whether a free capacity of the nonvolatile area 330 is enough may be determined. For example, whether a free capacity of the nonvolatile area 330 is larger than a capacity of write requested data may be determined. If the free capacity is enough, the nonvolatile area 330 may be accessed (operation S970). If the free capacity is not enough, the method proceeds to operation S960.

In operation S960, the nonvolatile area 330 may increase, and the volatile area 340 may decrease. In example embodiments, a memory controller 220 of FIG. 6 may decrease a size a delete area DA of a nonvolatile random access memory 230 and increase a size of a delete area 221. Then, in operation S970, the nonvolatile area 330 may be accessed. Sizes of the nonvolatile area 330 and the volatile area 340 may be adjusted according to a size of data to be stored. Sizes of the nonvolatile area 330 and the volatile area 340 may be adjusted, according to a predetermined value.

With the exemplary embodiments, in the case that a free capacity of the nonvolatile area 330 write requested is not enough, cold data of the nonvolatile area 330 may be moved to the storage 360. Thus, a write request may be processed without errors by securing a free capacity of the nonvolatile area 330.

The method of FIG. 14 may be applied to the case that the nonvolatile area 330 is a non-delete area NDA, and the case that a volatile area 340 is a delete area DA.

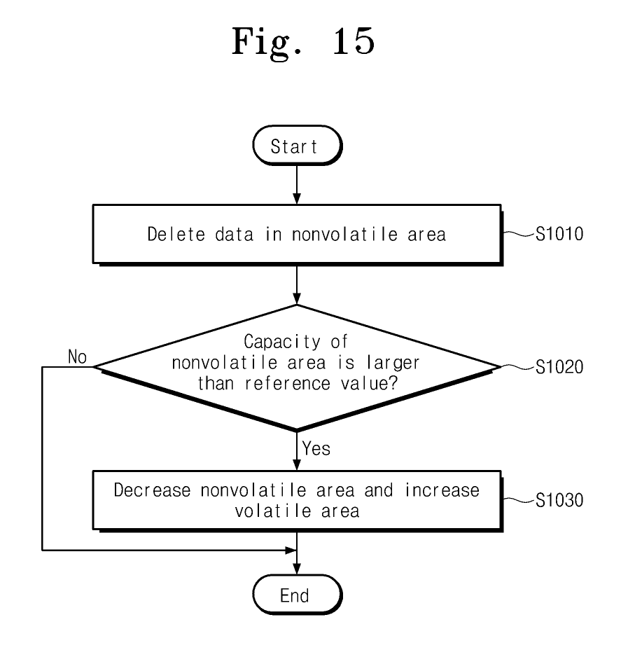

FIG. 15 is a flow chart illustrating still another method in which an operating system of FIG. 10 manages a nonvolatile area and a volatile area. Referring to FIGS. 10 and 15, in operation S1010, an operating system 320 may delete data of a nonvolatile area 330. The operating system 320 may receive a delete request from an application program 310 to delete data, according to a delete request. The operating system 320 may sense delete of the application program 310 to delete data associated with the deleted application program. The operating system 320 may delete data according to a predetermined schedule. The delete may include delete of data stored at a nonvolatile area 330 or invalidation of data through updating of a nonvolatile data table NDT.

In operation S1020, whether a free capacity of the nonvolatile area 330 is larger than a reference value may be determined. For example, whether a capacity of the nonvolatile area 330 is larger than an initial size may be determined. For example, whether a free capacity of the nonvolatile area 330 is larger than a reference value may be determined. The reference value may be a capacity corresponding to a specific ratio of the whole capacity of the nonvolatile area 330.

If a capacity of the nonvolatile area 330 is larger than the reference value, the nonvolatile area 330 may decrease and the volatile area 340 may increase (operation S1030). Sizes of the nonvolatile area 330 and the volatile area 340 may be adjusted according to a size of deleted data. Sizes of the nonvolatile area 330 and the volatile area 340 may be adjusted according to a predetermined value.

With exemplary embodiments, a part of a working memory of a computing device may be managed to be volatile, and another part thereof may be managed to be nonvolatile. Important data may be managed at a nonvolatile memory, and auxiliary data may be managed at a volatile memory. Thus, it is possible to provide a computing device having improved operating performance and an operating method of the computing device.

While the exemplary embodiments have been described with reference to exemplary embodiments, it will be apparent to those skilled in the art that various changes and modifications may be made without departing from the spirit and scope of the exemplary embodiments. Therefore, it should be understood that the above embodiments are not limiting, but illustrative.

What is claimed is:

1. A computing device comprising:
a first random access memory;
a second random access memory;
a memory controller configured to control the first random access memory and the second random access memory; and
a processor configured to use the first random access memory and the second random access memory as a working memory, through the memory controller,
wherein the memory controller is configured to access one memory, selected by a transferred command from the processor, from among the first random access memory and second random access memory.

2. The computing device of claim 1, wherein the first random access memory is a nonvolatile random access memory, and the second random access memory is a volatile random access memory.

3. The computing device of claim 2, wherein the memory controller accesses the second random access memory when a normal access command is transferred from the processor, and the memory controller accesses the first random access memory when a nonvolatile access command is transferred from the processor.

4. The computing device of claim 2, wherein the memory controller is configured to manage a nonvolatile data table which includes information on data stored at the first random access memory.

5. The computing device of claim 4, wherein the nonvolatile data table includes information on an address where data is stored, a process associated with the data, and an identifier of the data.

6. The computing device of claim 4, wherein the memory controller is configured to store the nonvolatile data table at the first random access memory.

7. The computing device of claim 6, wherein, when the computing device is powered, the memory controller is configured to read the nonvolatile data table from the first random access memory.

8. The computing device of claim 1, wherein the first random access memory is a first portion of a nonvolatile random access memory, and the second random access memory is a second portion of a volatile random access memory.

9. The computing device of claim 8, wherein, when the computing device is powered, the memory controller is configured to reset the second random access memory.

10. The computing device of claim 8, wherein the memory controller is configured to reset the second random access memory when a normal reset command is received from the processor.

11. The computing device of claim 8, wherein the memory controller is configured to reset the first random access memory when a nonvolatile reset command is received from the processor.

12. An operating method of a computing device which uses a first random access memory and a second random access memory as a working memory, comprising:
generating data;
determining whether the generated data is a first type data or a second type data; and
storing the generated data at the first random access memory when the generated data is the first type data, and storing the generated data at the second random access memory when the generated data is the second type data.

13. The operating method of claim 12, wherein the first type data is data managed to be nonvolatile, the second type data is data managed to be volatile, the first random access memory is a nonvolatile random access memory, and the second random access memory is a volatile random access memory.

14. The operating method of claim 12, further comprising:
generating a first type additional data;
determining whether a free storage capacity of the first random access memory is larger than a capacity of the first type additional data;
storing the first type additional data at the first random access memory when the free storage capacity is larger than the capacity of the first type additional data; and
moving cold data of data stored at the first random access memory to a storage when the free storage capacity is smaller than the capacity of the first type additional data, and storing the first type additional data at the first random access memory.

15. The operating method of claim 14, further comprising:
generating an access request of the first type data;
determining whether the first type data corresponding to the access request is stored at the storage;
accessing the first type data when the first type data is stored at the first random access memory and not stored at the storage; and
moving the first type data to the first random access memory when the first type data is stored at the storage, such that the first type data is accessed at the first random access memory.

16. The operating method of claim 14, further comprising:
deleting data stored at the first random access memory; and
moving cold data, which is stored at the storage, to the first random access memory when the free storage capacity of the first random access memory is larger than a reference value according to the deleting.

17. The operating method of claim 12, wherein the first type data is data managed to be nonvolatile, the second type data is data managed to be volatile, the first random access memory is a first area of a nonvolatile random access memory, and the second random access memory is a second area of a volatile random access memory.

18. The operating method of claim 17, wherein, when the computing device is powered, the first random access memory is not reset and the second random access memory is reset.

19. The operating method of claim 17, further comprising:
generating a first type additional data;
determining whether a free storage capacity of the first random access memory is larger than a capacity of the first type additional data; and
storing the first type additional data at the first random access memory by decreasing a capacity of the second random access memory by a reference capacity and increasing a capacity of the first random access memory by the reference capacity, when the free storage capacity is less than the capacity of the first type additional data.

20. The operating method of claim 19, further comprising:
deleting data stored at the first random access memory; and
decreasing a storage capacity of the first random access memory by a reference value and increasing a storage capacity of the second random access memory by the reference value, when the free storage capacity of the first random access memory is larger than the reference value according to the deleting.

21. An operating method of a memory controller in a computing device, comprising:
receiving an access request of a first random access memory from a processor;
accessing the first random access memory according to the received access request of the first random access memory;
updating a first random access memory table stored in the first random access memory;
receiving an access request of a second random access memory from the processor; and
accessing the second random access memory according to the received access request of the second random access memory.

22. The operating method of claim 21, wherein the first random access memory is a nonvolatile random access memory, and the second random access memory is a volatile random access memory.

23. The operating method of claim 21, wherein the access request of the first random access memory includes a first address or a first command, which indicates the first random access memory, and the access request of the second random access memory includes a second address or a second command, which indicates the second random access memory.

24. The operating method of claim 21, wherein the access request of the first random access memory is based on the first random access memory table stored in the first random access memory.

25. The operating method of claim 21, wherein the access request of the second random access memory is not based on a separate table.
